(19) United States
(12) Patent Application Publication
(10) Pub. No.: US 2024/0034847 A1
(43) Pub. Date: Feb. 1, 2024

(54) METHOD FOR NANOMATERIAL DISTRIBUTION WITHIN A MATRIX MATERIAL

(71) Applicant: Irradiant Technologies Inc., Cambridge, MA (US)

(72) Inventors: Daniel Oran, Cambridge, MA (US); Amos Meeks, Arlington, MA (US); Sheilan Sinjari, Cambridge, MA (US)

(21) Appl. No.: 18/363,330

(22) Filed: Aug. 1, 2023

Related U.S. Application Data
(60) Provisional application No. 63/394,101, filed on Aug. 1, 2022.

(51) Int. Cl. C08J 3/28; C08K 3/22; C08K 3/30; G03F 7/004

(52) U.S. Cl. CPC C08J 3/28; C08K 3/22; C08K 3/30; G03F 7/0044; C08K 2201/011; C08K 2003/2286; C08K 2003/3009; B82Y 40/00

(57) ABSTRACT

A method for nanomaterial formation and distribution within a matrix material that includes: preparing a gel matrix; patterning a reactive group within the matrix material; binding a seed material to reactive group within the matrix material, the seed material selected from a first set of gold nanomaterials, silver nanomaterials, and copper nanomaterials; binding a precursor reagent selected from materials to the seed material; adding a chalcogen to form a precursor reagent chalcogenide at sites of the precursor reagent via an ion exchange; adding final compound and optionally a ligand in solution and facilitating cation exchange replacing the precursor reagent chalcogenide with the final compound to form a nanomaterial within the matrix material.

### CROSS-REFERENCE TO RELATED APPLICATIONS

This application claims the benefit of U.S. Provisional Application No. 63/394,101, filed on 1 Aug. 2022, which is incorporated in its entirety by this reference.

### TECHNICAL FIELD

This invention relates generally to the field of nanomaterial formation, and more specifically to a new and useful system and method for nanomaterial assembly within a gel matrix.

### BACKGROUND OF THE INVENTION

In all fields, with the progress of science and technology, there has always been a strong impetus to create and understand tools and devices of smaller and more precise scales. This has been true both in the biological fields (e.g., construction of cellular level nanomachines and molecular motors), as well as in the technological fields (e.g., the development of semiconductors and ever-increasing complexity of multidimensional microchips). To this date, there are many tools and approaches used for constructs of smaller sizes. But as we reach smaller scales and enter the quantum scale, the tools available are severely limited, as the complexity to manipulate and create objects becomes significantly more complex.

As to date, there is limited development for manipulation and assembly of particles within a matrix material on a nanometer scale. Thus, there is a need in the field of nanofabrication to create a new and useful method for particle assembly and pattern formation in a matrix material. This invention provides such a new and useful system and method.

### BRIEF DESCRIPTION OF DRAWINGS

FIG. 1 is a graphical representation of a method variation.

FIG. 2 is a flowchart representation of a first method variation.

FIG. 3 is a flowchart representation of a method variation involving seeding of a matrix material.

FIG. 4 is a flowchart representation of a method variation involving preparing a matrix material.

FIG. 5 is a flowchart representation of a method variation involving patterning the matrix material.

FIG. 6 is a flowchart representation of a method variation involving introducing of a ligand solution.

FIG. 7 is a flowchart representation of a method variation involving multiple iterations for two passes of producing nanomaterials of potentially different types.

### DETAILED DESCRIPTION OF THE EMBODIMENTS

The following description of the embodiments of the invention is not intended to limit the invention to these embodiments but rather to enable a person skilled in the art to make and use this invention.

1. Overview

A method for the assembly of a desired particle in a matrix material involves distributing a reactive group in a matrix material such as a polymer matrix or a gel, wherein the reactive group binds the matrix material; providing a nucleation site on the reactive groups; growing a precursor reagent; converting the precursor reagent to a chalcogenide particle; and replacing the chalcogenide particle with the desired particle. The desired particle in some variations is a nanomaterial.

The method functions to enable distribution or patterning of nanomaterials within a matrix material such as a polymer matrix or gel matrix. The matrix material functions as a scaffold that can facilitate a sequence of reactions to occur. As the reactive group may be specifically patterned, or generally distributed, throughout the matrix material, the method functions to generally assemble the desired particle throughout the matrix material, and/or specifically pattern the matrix material with the desired particle.

The method may be used in the formation of nanomaterials such as a nanoparticle, nanomaterial-composition, and/or nanostructure. The formed nanomaterials may be particle assemblies where individual instances of a desired nanomaterial are formed distributed through the matrix material. In another variation, the method may be used in forming a complex nanostructure, which could be a solid instead of a particle assembly. Such complex nanostructures could include lattices, wires, films, or any suitable structures.

In some variations, the method may be used to make Core-Shell structures. In such variations, an additional layer of material may be grown on top of a seed particle or structure. The material may be a metal or a metal chalcogenide. The material may alternatively be of other varieties. For example, silica shells using siloxanes may be used to passivate particles. Within the method, such Core-Shell structures may be grown on seed materials, precursor reagents or on a final (or intermediary) composition. In some variations, the Core-Shell structure may be the final composition. In another variation, the Core-Shell structure may be used for passivation. In another variation, after formation of the Core-Shell structure, the material may undergo the other processes of the method to form a new composition building from the Core-Shell structure.

The method described herein may be achieved with mild conditions and materials and possibly without using volatile solutions or high temperatures. In some variations, the method may be performed using an aqueous solution, using room temperatures or low heat (e.g., 50° C.).

Using the matrix material as a scaffold can serve as an improvement over previous solution-based approaches to producing nanomaterials. Because the materials are bound to the polymer or material of the matrix material, the particles don't have to be kept in solution or have some other processes/conditions (e.g., high temperatures or using volatile solutions) to maintain suspension.

The method may be used in forming nanomaterials and/or various nanomaterial-based components. The method may be used in forming nanoparticles or more complex nanostructures. A more complex nanostructure that may be formed through the method may include solid assemblies, which could include lattices, wires, films, and/or other types of nanostructures.

The method may be used for producing nanomaterials for any suitable application such as photonics, semiconductors, thermoelectronics, spintronics, memory, magnets and other areas of applications. The method may be particularly useful in applications where the use of Chalcogenides is used.

In one particular area of use, the method may be used to pattern nanomaterials relevant to optical photonic components and applications. Such nanomaterials may include chalcogenides, in particular metal chalcogenides and/or Perovskites. This may be used to create high refractive index material. In some variations, the method may be used in forming nanomaterials that are high refractive index metal chalcogenides such as Cadmium, Zinc, Silver, Lead, Tin, Antimony, Silver, Copper, Bismuth, Iron, Gallium, sulfides, selenides and tellurides, and/or mixtures of these. Nanomaterial structures of such metal chalcogenides may be useful for creating lensing or other optical components to manipulate light.

As a list of exemplary applications, the nanomaterials produced through the method may be used in forming optical components, such as lenses, prisms, waveguides, gratings, mirrors, filters, beam splitters, waveplates, polarizers, photonic crystals, optical isolators, interferometers, couplers, multiplexers, beam steerers, meta-optical devices, acousto-optic devices, and/or other optical components. The nanomaterials may additionally or alternatively be used for other types of electronic devices or components such as wires, resistors, capacitors, inductors, transistors, diodes, etc. and combined electro-optic devices, such as a thermal Mach-Zehnder interferometers, piezoelectric components, thermoelectric components, solar panels, light emitters (LEDs, Lasers), nonlinear effects (upconversion, downconversion, fluorescence, phosphorescence), and/or other types of devices or components.

Some chalcogenides can be useful materials for achieving changes in refractive index as their refractive index may be changed with temperature, phase, electrical field, current/voltage, light (absorption), and/or pressure. When patterned within the matrix material, this may enable active optical components that could change refractive index, change focus, deflect light by different amounts by changing/modulating the temperature, passing current through it, or other changes.

The method may use patterning processes to spatially select where in the matrix material the nanomaterials are formed. Patterning may be used to vary spatial arrangement in the matrix material along one-dimension, two-dimensions, or three-dimensions.

Alternatively, the method may be modified to be a bulk process where uniform depositing of the nanomaterials is performed in bulk throughout the matrix material.

The method may be used to pattern nanomaterials in a variety of ways within the matrix material. In some variations, the nanomaterials may be patterned within matrix material in a substantially uniform manner—where nanomaterials are regularly spaced and distributed within the matrix material. The matrix material (e.g., gel) may be of arbitrary shape and size. In some variations, the gel could be a sheet or a block, but the gel may any regular or irregular shape. In some variations, patterning may be used to selectively form the nanomaterials in particular regions. Different two-dimensional or three-dimensional patterns of nanomaterials may be established within the gel matrix. This may be used to make gradients of nanomaterials.

In some variations, the patterning of nanomaterials throughout a matrix material may be used as a process in generating nanomaterials. In some variations, the nanomaterials formed as part of a final composition may be in a particulate composition where multiple instances of desired nanomaterial particles (i.e., nanoparticles) are distributed through the matrix material. In some variations, the final composition may include continuous solid of desired nanomaterials. After formation of the nanomaterials in the matrix material, the gel matrix may be dissolved or otherwise broken down after the formation of the desired nanomaterials, possibly with additional filtering, leaving behind nanomaterials without the gel matrix. The use of a matrix material like a gel may be used to control how the nanomaterials form (e.g., controlling direction and shape). The nanomaterial production process of the method may also be used to facilitate production of solid, possibly complex, nanomaterial structures that may be challenging to construct or not even feasible in solution.

As the method uses generally biologically friendly compounds, the method may provide a broad range of use cases for nano-scale pattern formation in both biological (e.g., biocompatible) and non-biological settings.

The method may provide a number of potential benefits. The system and method are not limited to always providing such benefits and are presented only as exemplary representations for how the system and method may be put to use. The list of benefits is not intended to be exhaustive and other benefits may additionally or alternatively exist.

As one potential benefit of the method, the method provides a new means of particle assembly in a matrix material without synthesizing the final particle composition in advance.

The method employs air-stable materials and mild synthetic conditions. As common methods available today require an inert atmosphere and high temperatures (e.g., >100° C.), the method provides the potential benefit of enabling implementation under ambient conditions.

As another potential benefit, the matrix material serves as a scaffold that can avoid or reduce occurrences of aggregation of nanomaterials. The nanomaterials can be formed with defined spacing within the matrix material. As a related potential benefit the nanomaterial does not need to remain in suspension as the matrix material can act as a supporting scaffold that holds the nanomaterial in place, thus, expanding the range of available/compatible chemistries. For instance, surface ligands may no longer be necessary to keep particles from aggregating or falling out of suspension.

Another potential benefit is that particle concentration can be patterned in 3D with nanoscale resolution for the fabrication of functional optical, electronic, or other kinds of devices. Furthermore, particles can be co-patterned with other kinds of nanomaterials, or co-patterned with removed regions of the polymer matrix, for further functionality.

As another potential benefit, the method may be used to achieve high fill fractions or continuous solids from useful dielectric or semiconductors. This may be used to form a high mobility semiconductor, quantum dots, and/or other such materials.

2. Method

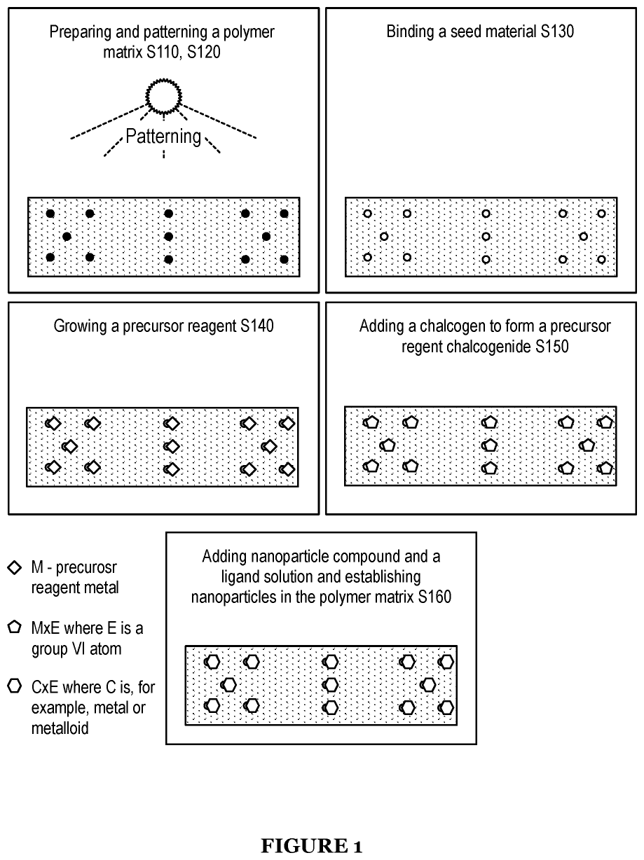

A method for nanomaterial assembly (or assembly of another type of desired final compound) in a matrix material functions to disperse a desired compound (i.e., final compound) throughout a matrix material (or gel). The method uses sequential exchanges (e.g., ion exchanges) of materials to move from a material that can be dispersed through the matrix material to the eventual desired final compound as shown in FIG. 1, which in some variations is a nanomaterial of some form. In some variations, the method establishes growth regions or seeds in the matrix material and then facilitates one or more ion exchanges to form nanomaterials of a desired composition.

The method uses a process where a precursor reagent can be bounded at sites within a material matrix (e.g., using patterning and binding seed material) and then controlled ion exchanges can be used to exchange one ion for another within a particle. Some cations used in the ion exchange can include Ag, Cd, Zn, Pb, Sn. A mixture of cations may also be used. The number of exchanges could be any suitable number and so while the method is primarily discussed below as a linear process, there may be multiple iterations of some steps with different materials. For example, Ag could be exchanged for Cd in AgS to create CdS. Then Cd could be exchanged for Zn to make ZnS. Alternatively, Zn could be allowed with another material such as ZnPbS. Any cations may be swapped out in any order and/or mixed.

Depending on implementation, the final compound may be: homogeneously dispersed throughout the entire matrix material, or some region of the matrix material; heterogeneously dispersed randomly throughout the matrix material, or heterogeneously dispersed in an organized manner (e.g., along a spatial concentration gradient or positioned in a distinct patterned) throughout the matrix material. The method may or may not use patterning of binding sites (e.g., via a reactive/binding group) to spatially select where the nanomaterials may form within the matrix material. In alternative variations, bulk seeding of the matrix material may be used.

In execution, the method facilitates binding at least a precursor reagent which is preferably a precursor metal (M) within regions of a matrix material. The matrix material serves as a scaffold to prevent aggregation of nanomaterials and to facilitate more easily achieved reaction conditions (e.g., no stirring, possibly no or lower heating requirements, avoiding volatile chemicals). The precursor metals are deposited or grown onto templated material bound to the matrix material or patterned regions. Introduction of chalcogen (E) enables reaction forming particles of the form M×E at the seeded sites in the matrix material. Here E is a group VI atom (e.g., O, S, Se, Te, Po, Lv) and M is a corresponding atom, generally a metal intermediate (e.g., Cd, Zn, Ag, Pb, Sn, Ag, Cu, Bi, Fe, Ga). Then introduction of final compound (C) can be introduced to form particles of the form C×E through an ion exchange. C may be any metal or metalloid. In some variations C may be selected from a list of Alkali metals, Alkaline Earth Metals, Transition metals, Post-transition metals or any suitable metal or metalloids in groups to the left of S, Se, and Te. In some variations, a ligand may be introduced (e.g., in solution) to facilitate cation exchange. This method may be used to form a desired nanomaterial distributed within the matrix material.

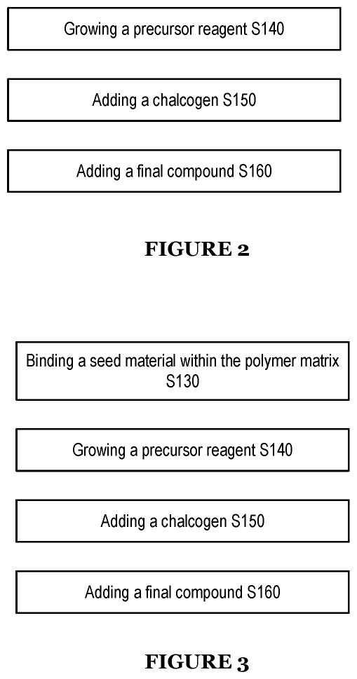

The method includes a process of establishing a precursor reagent within a matrix material, and then using that as a building block for forming a desired final compound, more particularly a nanomaterial final compound. The method may generally include, as shown in FIG. 2, growing a precursor reagent in a matrix material S140; adding a chalcogen to form precursor reagent chalcogenide S150; and adding a final compound, facilitating an ion exchange and replacing the precursor reagent chalcogenide with the final compound S160.

In some variations, the precursor reagent may be established by reacting it to seed materials distributed through the matrix material. In such a variation, a method variation, as shown in FIG. 3, may be more particularly described as: binding a seed material within a matrix material, establishing nucleation sites S130; at the nucleation sites, growing a precursor reagent S140; adding a chalcogen to form precursor reagent chalcogenide S150; and adding a final compound, facilitating an ion exchange and replacing the precursor reagent chalcogenide with the final compound S160.

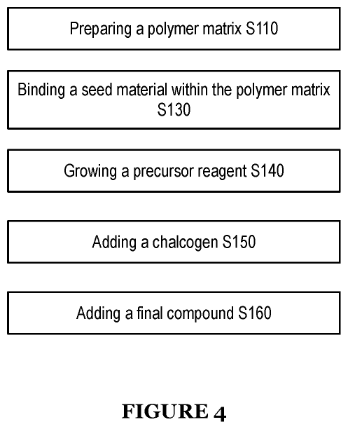

In some variations, the matrix material may be provided pre-treated or otherwise come with reactive groups bound within material of the matrix material. The seed material can then bind and establish position within the matrix material by reacting to the reactive groups. As such the method of some variations, as shown in FIG. 4, may include preparing a matrix material S110; binding a seed material within the matrix material, establishing nucleation sites S130; at the nucleation sites, growing a precursor reagent S140; adding a chalcogen to form precursor reagent chalcogenide S150; and adding a final compound, facilitating an ion exchange and replacing the precursor reagent chalcogenide with the final compound S160.

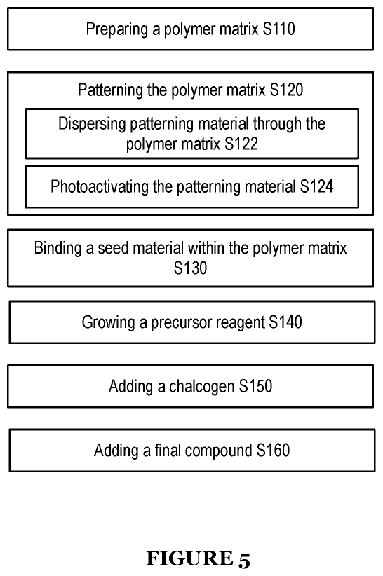

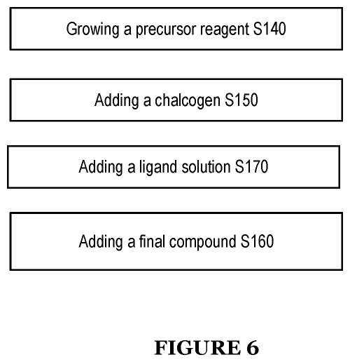

In some variations, the reactive groups may be bound to the matrix material through a patterning process. This patterning process may be used to establish the final compound dispersed within the matrix material with any suitable spatial pattern (e.g., 1D, 2D, or 3D pattern). As shown in FIG. 5, a method variation for patterning the final compound may include: preparing a matrix material S110; patterning the matrix material S120; binding a seed material within the matrix material, establishing nucleation sites S130; at the nucleation sites, growing a precursor reagent S140; adding a chalcogen to form precursor reagent chalcogenide S150; and adding a final compound, facilitating an ion exchange and replacing the precursor reagent chalcogenide with the final compound S160.

In some variations, the method may involve the introduction of a ligand to facilitate ion exchange to establish the nanomaterials at the sites of the precursor reagent chalcogenides. Method variations using a ligand in the reaction may include growing a precursor reagent in a matrix material S140; adding a chalcogen to form precursor reagent chalcogenide S150; adding a ligand solution S110, and adding a final compound, facilitating an ion exchange and replacing the precursor reagent chalcogenide with the final compound S160. The ligand variation may be used within any suitable variation described herein.

As some applications of the method variations may be very implementation specific (e.g., the implementation may depend on the desired final compound, type of gel used, implementation environment, type of patterning, etc.), method steps may have many alternate variations. For this reason, method steps may vary or be completely removed dependent on implementation. For example, in some variations patterning is not necessary (i.e., block S120 unnecessary), some precursor reagents do not require seeding (i.e., block S130 unnecessary), and some final compound implementations do not require a precursor reagent (i.e., block S140 unnecessary).

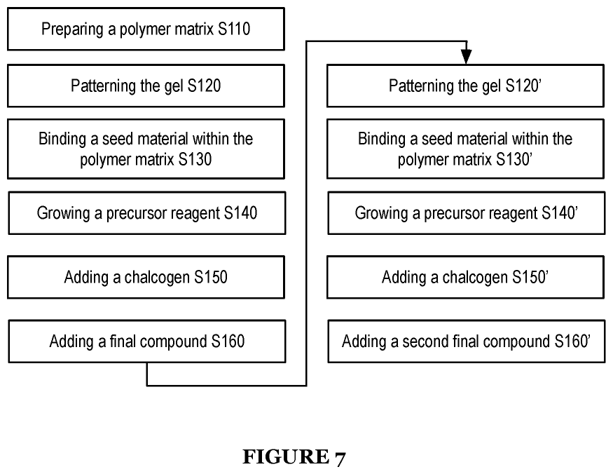

In some implementations, the method may enable distribution of more than one type of final compound throughout the matrix material. There may be a particle or nanostructure that doesn't participate in ion exchange. There could be a particle or nanostructure that can participate in ion exchange but is somehow differently reactive or exhibits a different result. There could be another particle or nanostructure of a different material that may be similarly reactive. In another variation, a first finally produced nanomaterial may be passivated while exchange is performed on another kind of particle/nanostructure for sequential material alterations and/or additions. For one “multi-final compound” implementation, the method steps (beyond block S110) may be implemented to completion for a first final compound, implemented again for a second final compound, again for a third final compound, and so on. As shown in FIG. 7, a method for establishing multiple final compounds (e.g., two different types of nanomaterials), may include establishing a first final compound in a matrix material comprising: preparing a matrix material S110, patterning a reactive group within the matrix material (S120), binding a seed material within the matrix material, establishing nucleation sites S130, at the nucleation sites, growing a precursor reagent S140, adding a chalcogen to form precursor reagent chalcogenide S150, adding a final compound, facilitating an ion exchange and replacing the precursor reagent chalcogenide with the final compound S160; and establishing a second final compound in the matrix material comprising: preparing the matrix material S110′, patterning a second reactive group within the matrix material (S120′), binding a second seed material within the matrix material, establishing second nucleation sites S130′, at the second nucleation sites, growing a second precursor reagent S140′, adding a second chalcogen to form precursor reagent chalcogenide S150′, and adding a second final compound, facilitating a second ion exchange and replacing the second precursor reagent chalcogenide with the second final compound S160′. This may include passivating the final compound prior to the These secondary elements may all or partially be the same or different or different) from the initial pass of the method. The pattern formed in some variations can be different such that different resulting nanomaterials can be patterned within the matrix material in a desired pattern.

This may be used to pattern different distinct types of nanomaterials. They could be produced in an organized spatial arrangement when using patterning. They may also be used to pattern the same type of nanomaterials but doing it in stages as a way of controlling concentration or other properties of the produced nanomaterial-laced matrix material.

The method may be performed at a variety of conditions. As discussed, some applications of the method may enable nanomaterial production with sufficiently easier production conditions. For example, the method and in particular blocks S130, S140, S150, and/or S160 may be performed at a temperature range of 20° C.-100° C. In some variations, the method (or one or more stages of the method) may be performed at higher temperatures greater than 100° C. Low temperature conditions may be a unique feature for producing nanomaterials like Cadmium Sulfide (CdS) nanomaterials. In some instances, higher temperatures greater than 100° C. (e., 100-400° C.) may be used for producing lead compounds or tellurides (e.g., PbS, PbSe, CdTe, and the like). In some instances, elevating temperature may be used to accelerate the process or to facilitate certain reactions.

Block S110, which includes preparing a matrix material, functions to obtain and setup a base platform or scaffold for forming the final compound. That is, the matrix material functions as a scaffold for nanomaterial distribution. In some cases, the matrix material functions as a multi-dimensional scaffold for spatial nanofabrication. Based on implementation, preparing a matrix material S110 may comprise making and setting up a gel (or other form of matrix material) or providing a matrix material through some other means (e.g., using a pre-prepared/formed gel, extracting, etc.). In some variations, the matrix material may be a naturally biologically occurring gel (e.g., an actin filament matrix, or a cellulose matrix). As another alternative variation, the matrix material may be a porous silicon or silica instead of gel.

Herein, the term matrix material may be used to refer to each individual matrix material molecule, a group of matrix material molecules, all matrix material molecules, or any subset therein.

As used herein, the terms: matrix material, gel matrix, polymer matrix, and gel may be used interchangeably. As used herein, these terms all refer to one, or multiple polymer compounds that provide the scaffold for the nanomaterial distribution. Dependent on implementation, polymers may be linear filaments, branched filaments, or hyperbranched filaments. Dependent on implementation, the polymer may or may not be cross-linked together forming a polymer mesh of some desired density. Alternatively, the “matrix material” may comprise individual polymer strands. That is, in some variations, the matrix material may comprise an individual polymer filament (or multiple distinct polymer filaments), wherein as part of the method, the desired final compound may be dispersed along each individual filament.

Preparing the matrix material S110 can include introducing the matrix material or medium to a solvent. The matrix material is preferably in some form of solvating medium during the whole process. The solvating medium may include polar protic and polar aprotic solvents. In some alternative variations, the solvent could include apolar solvents such as when using a hydrophobic gel as the matrix material. In some examples, the solvating medium may be water for all or most steps of the method. In some variations, the method may include changing the solvating medium, which may function to use a solvating medium to facilitate a desired reaction. For example, the method may include changing the solvating medium may be changed from water to another polar solvent.

The solvating medium may facilitate matching the solubility of the desired final compound to the precursor reagent chalcogenide in the matrix material. Examples of a solvating mediums include: polar protic solvents (e.g., water, Methanol MeOH, Ethanol EtOH, Isopropyl alcohol), polar aprotic solvents (e.g., Dimethyl Sulfoxide DMSO, Dimethylformamide DMF, acetone), and non-polar solvents (e.g., Propylene Glycol, toluene, xylenes, benzene, hexanes and general hydrocarbon solvents, acetonitrile, halogenated solvents like DCM, and chloroform). In some variations, mixtures of solvents may be used. Solvent mixtures can include reagents that may, or may not, be miscible. Dependent on implementation, vigorous mixing, or adding a compound soluble in multiple phases, may facilitate mixing of the solvent mixture.

Dependent on implementation, the matrix material may be naturally occurring or synthetically produced. Dependent on implementation, the matrix material may be composed of a single polymer compound or multiple polymer compounds. Dependent on implementation, the polymer may comprise a simple polymer (e.g., polysaccharide built of single molecule monosaccharide monomers) or complex polymers (e.g., microtubules built of complex multi-protein tubulin monomers). Examples of synthetic polymers that may be incorporated include: vinyl monomers (e.g., (meth)acrylates, (meth)acrylamides, styrenes, vinyl esters, vinyl ethers, anhydrides), ring-opening monomers (e.g., caprolactams, caprolactones, cyclic ketene acetals), and condensation monomers (e.g., diamines, dicarboxylic acids, ethylene glycol, epoxides). Examples of natural polymers include: polysaccharides (e.g., agarose, chitosan, hyaluronic acid and alginate, cellulose) gelatin, and polyhydroxyalkanoates (e.g., PH3B, PHV).

The matrix material may be a material of any suitable shape or form. The matrix material may be a material formed in a rectangular sheet (or any suitable sheet with shaped outline) with some thickness. In some variations it may be a thin film. In still other variations, the matrix material may be of any suitable geometry and may be a molded or formed shape with any suitable form or profile. For example, matrix material may have a shape profile conforming to some shape desired for an optical/photonic element (e.g., being a lens or cover/film on a lens). The matrix material may additionally be bound, coupled, or contained within some other element depending on the desired application.

The matrix material is prepared and selected for suitability for an option of patterning of reactive group within the matrix material. In many variations, the matrix material is unreactive with other system components other than the latent patterning material (e.g., reactive group materials). Alternatively, the matrix material may be reactive to other components. For example, in one variation the system may further include a masking component, wherein the matrix material may selectively bind the masking component. This selective binding (e.g., to the masking component) may block the matrix material to prevent the binding of the reactive groups.

In many variations, the matrix material may comprise a cross-linked (i.e., crosslinkers) polymer network. The matrix material may have physical or covalent crosslinks, inherent or implemented, as part of the multidimensional matrix material. For example, a polyacrylate gel may have N,N′-Methylene-bis(acrylamide) cross-linkers. In some variations, this polymer network is generated from one, or more, vinyl monomers. The vinyl monomers may be acrylic or acrylamide monomers bearing side groups, wherein these side groups may, or may not, be inert to reaction with other system components, other than latent patterning material. In some variations, the matrix material is covalently cross-linked via radical polymerization with a diacrylamide monomer. In other variations, dimethacrylamides, diacrylates, dimethacrylates, divinylethers, and suitable hydrophobic or hydrophilic divinyl monomers may be used to generate covalent cross-links.

In some variations, the matrix material may be composed of hydrophobic, or hydrophilic, vinyl monomers. As used herein, the term “hydrophilic monomer” describes a monomer which, when polymerized, yields a polymer that either dissolves in water, or is capable of absorbing at least 10%, by weight, of water under ambient (i.e., 20° C.) conditions. Similarly, as used herein, the term “hydrophobic monomer” describes a monomer, which when polymerized, yield a polymer that neither dissolves in water, nor is capable of absorbing at least 10% water, by weight, under ambient conditions. Examples of suitable monomers may include methacrylates, acrylates, styrenes, methacrylamides, acrylamides, silyl-containing monomers.

The matrix material may include a side group. More specifically, a matrix material molecule, or a group of matrix material molecules, may have a side group, or multiple side groups. The side group functions to provide a binding site for the latent patterning material. The side group may be any desired side group that can be used for binding of the latent patterning molecules. Examples of potential side groups include, but are not limited to: carboxylic acids, sulfonic acids, phosphoric acids, primary amines, quaternary amines, amides, hydroxides, and/or sulfonates. Dependent on the implementation, the matrix material may incorporate one, or multiple, side groups. Multiple side groups may enable binding of multiple types of latent patterning materials, other components (e.g., a masking component), and/or provide binding with different binding strengths (e.g., to enable a gradient effect binding).

In some variations where the matrix material comprises vinyl monomers, the vinyl monomers may have the side group(s). Examples of side groups include: carboxylic acid, sulfonic acid, phosphoric acids, primary, secondary, tertiary and quaternary amines, hydroxyl, thiols and thioesters, amides and acetates. As used herein, side groups such as “carboxylic acids”, “sulfonic acids”, or “phosphoric acids” include the free acid moiety and corresponding metal salts of the acid moiety, as well as ester derivatives of the acid moiety, including without limitation alkyl esters, aryl esters and acyloxyalkyl esters. In some variations, the gel may be composed of naturally occurring polymer, such as agarose, alginate or other polysaccharides. In some variations, the gel may be composed of charged monomers, such as acrylic acid, 2-(dimethylamino)ethyl methacrylate, sulfonated monomers, or others.

Block S120, which includes patterning the matrix material, functions to load the matrix material with a reactive group, wherein the reactive group may function as an intermediary for nucleator binding. Patterning the matrix material may be more particularly described as patterning a reactive group within the matrix material. The reactive group binds within locations of the matrix material. The reactive group functions as the positioning intermediary for the desired final compound. Thus, how the reactive group is patterned onto the matrix material directly affects the position of the final compound.

The reactive group functions as a mechanism to facilitate bonding which may include chemical bonding (e.g., chemical interaction for conjugation, seeding/deposition/growth, or radical generation/polymerizationor, etc.) and/or non-chemical bonding (e.g., physical kind of bonding like Van Der Waals, electrostatic, hydrogen bonding, Hydro-philic/phobic and Oleo-philic/phobic interactions and partitioning, and/or other forms of intermolecular interactions other than chemical bonding). Herein, reactive group (or more generally referred to as a binding group) may a refer to any chemical group, moiety, or molecule that causes the desired material to be bound or deposited in a desired area, whether through physical interactions (e.g. van der waals, electrostatic, hydrogen bonding, pi-pi stacking, topological/steric/geometric constraint), chemical bonding (e.g. formation of covalent or ionic chemical bonds), or nucleation and growth.

In some variations, block S120 may not be implemented. In these variations, the nucleator may directly bind to the matrix material and thus an intermediary may not be necessary.

As an alternative to patterning the matrix material, the method may use bulk processing of a matrix material, where a reactive group is uniformly loaded into the matrix material without any spatial biasing or steering. This may function to uniformly distribute reactive groups through the matrix material.

Patterning the matrix material S120 may use any method of loading/dispersion as desired. For example, patterning the matrix material S120 may include dispersing the reactive group into the matrix material and providing sufficient time for the reactive group to diffuse throughout the matrix material. Additionally or alternatively, patterning the matrix material S120 may include directed flow of the reactive group through the entire matrix material or regions of the matrix material.

Dependent on implementation, patterning the matrix material S120 may selectively or generally attach the reactive group to the matrix material. In particular, patterning the matrix material S120 may include dispersing a patterning material through the matrix material S122 and photoactivating the patterning material S124 as shown in FIG. 5. This functions to pattern the matrix material with desired reactive groups (e.g., to facilitate binding the seed material is S130. The patterning material preferably is or includes the reactive group and functions as a latent pattern material. That is, the reactive group may be: distributed homogeneously throughout the matrix material, or some region of the matrix material; distributed with some concentration gradient(s) throughout the matrix material, or some region of the matrix material; and/or distributed in some pattern. Herein this patterning material may be more concisely referred to as the reactive group, reactive group material, or reactive group compound. Any type of distribution may be used, as desired by implementation. In one example, the reactive group may have photoactivatable binding, as described in U.S. patent application Ser. No. 17/826,076, filed on 26 Jun. 2022, titled “SYSTEM AND METHOD FOR HIGH RESOLUTION 3D NANOFABRICATION”, which is hereby incorporated in its entirety by this reference. In this example, the reactive group may have photoactivatable matrix material binding capabilities, such that the reactive group may be patterned throughout the matrix material using light.

As an intermediary that binds the matrix material and nucleator, the specific composition of the reactive group may be dependent on implementation. Thus, the only true limitation of the reactive group is that it binds the matrix material and the desired seed particle (i.e., nucleator). The reactive group—which could involve primary amines, NHSs, carboxylic acids, hydroxyls, sulfhydrils, maleimides, alkenes, alkynes, azides, tetrazines, tetrazoles, difluorinated cycloocytne (DIFO), DIBOs, BARACs, DBCOs, biotins, avidins/streptavidins, proteins (e.g., antibodies/enzymes), nucleic acids (e.g., DNA, RNA, LNA, PNA), lipids (e.g., hydrocarbons, fluorocarbons), and dendrimers—may have additional binding sites, side groups, and the like, dependent on desired functionality. In some variations, the reactive group may be a chromophore with a matrix material binding site and a seed binding site. As part of the photoactivatable example, the matrix material binding site may be photoactivatable. Example chromophores include, but are not limited to: fluoresceins, rhodamines, squaraines, and cyanines.

In some variations, patterning the S120 may “pattern” the matrix material using multiple reactive groups. Patterning the matrix material S120 with multiple reactive groups may function to enable creation of more complex patterns throughout the matrix material. Additionally or alternatively, multiple reactive groups may enable implementation of multiple final compounds. Thus, multiple reactive groups may enable a final pattern construct that includes distinct final compounds, wherein each final compound is formed separately within the same matrix material. In these implementations, each reactive group may bind a distinct nucleator that facilitates nucleation of different compounds.

Preferably, the patterning material is a photosensitive material, such that photoactivating the patterning material enables a change in interaction between the gel and the patterning material (e.g., binding, unbinding). In its simplest form, regions of the gel that have photo-activated patterning material may become fixed in place or bound to the gel. By specifically photo-activating the patterning material in a manner to trace out the shape of the desired fabrication a mapping of the desired fabrication may be created by the bound patterning material. Unbound latent patterning material may then be washed away, leaving the desired patterning for the fabrication. For complex structures, patterning the gel S120, and its substeps, may be repeated multiple times until a final desired mapping of the fabrication is created. Photo-activation may use two-dimensional exposure or three-dimensional exposure techniques to activate the patterning material.

The patterning material (also referred to as chromophore, conjugation material, or dye) used for patterning the gel S120 may be of any desired type, or types, of material. That is, the patterning material may be a single compound or multiple distinct compounds, patterned on to the gel. This compound, or compounds, may pattern over distinct regions of the gel, or may be interspersed. The type, or types, of patterning material, and their dispersion may be implementation specific.

The patterning material may include a single, or multiple, functional molecules or molecule segments, wherein each single, or multiple molecules provides the patterning material with a functional desired property (e.g., phosphorescence, photosensitivity, binding site(s), increased/decreased solubility, etc.). Heretofore any functional property may be referred to as a “segment”, wherein a segment enables a specific functional property and may equally refer to part of a molecule, a single molecule, or multiple molecules, without any loss of generality.

The patterning material may comprise a reactive group segment. The reactive group segment comprises a reactive group utilized to enable binding of the build material. The reactive group segment may comprise any molecule(s) that can enable binding of the patterning material to the build material. In some variations, the reactive group segment may be turned on, or off (e.g., by allosteric binding or photo-activation). In some variations, the reactive group segment is always active. In some variations, the reactive group segment binding may only be activatable such that binding only occurs once the reactive group segment has been activated (e.g., by photoactivation). In an alternative variation, the reactive group segment may be initially active, such that the build material may directly bind to the patterning material. Activating the reactive group segment (e.g., through photo-activation) may then release the build material, such that it can be washed away, enabling patterning a construction by “erasure”.

In some variations, the number of reactive groups may be amplified by depositing a material that contains multiple reactive groups. In these variations, the method may further include amplifying the reactive group by depositing a reactive group rich compound. Amplifying the reactive group may function to increase the rate, and/or ability, of the patterning material to bind the matrix material. In some examples, depositing a reactive group rich compound comprises depositing poly(amido)amine.

In some variations, the patterning material does not include a reactive group segment, or includes a suboptimal reactive group segment (i.e., a reactive group segment that does not enable sufficient binding with the desired build material). In these variations, the method may further include: priming the patterning material. Priming the patterning material functions to add, or modify, a reactive group segment to the patterning material, such that the build material may better bind to the patterning material. Priming the latent patterning material may comprise creating, or obtaining, the desired molecular sequence and binding it to the patterning material. Alternatively, priming the patterning material may comprise, using molecular techniques to modify the current reactive group segment to the desired sequence. Alternatively, priming the patterning material may comprise using recombinant techniques to create the DNA precursor of the desired molecular sequence prior to producing the protein.

The reactive group segment may comprise any molecule(s) that enable build material binding. Examples of the conjugation segments include: primary amines, NHSs, carboxylic acids, sulfhydrils, maleimides, alkenes, alkynes, azides, tetrazines, tetrazoles, difluorinated cycloocytne (DIFO), DIBOs, BARACs, DBCOs, biotins, avidins/streptavidins, proteins (e.g., antibodies/enzymes), nucleic acids (e.g., DNA, RNA, LNA, PNA), lipids (e.g., hydrocarbons, fluorocarbons), and dendrimers.

The patterning material may comprise a photosensitive segment. The photosensitive segment may be functionally connected to the matrix material binding segment. The photosensitive segment functions as a light sensitive region of the patterning material, wherein light, of the appropriate wavelength, may be used to activate, or deactivate, binding of the matrix material binding segment. Thus, the photosensitive segment enables patterning the matrix material S120 by photoactivating the patterning material. In some alternative variations, the photosensitive segment may enable binding or unbinding of the reactive group segment.

In some variations, the multiple distinct types of latent patterning material may be incorporated (e.g., two distinct patterning material types wherein each one is associated with a different build material through distinct coordination sites). These variations may have patterning material where each type of patterning material has a photosensitive segment that is sensitive to a distinct light bandwidth, thereby patterning a first patterning material with photoactivation by a first light bandwidth will not affect patterning a second patterning material with photoactivation by a second light bandwidth. This may enable patterning the matrix material S120 with distinct patterning material such that each material may later bind to a different build material.

The photosensitive segment may be “light” sensitive to any desired bandwidth of the electromagnetic radiation set by the chemistry of the photosensitive segment. In some variations, the light sensitive region may comprise sensitivity to a light bandwidth that is on or near the visible spectrum (e.g., blue light, UV light, red light, infrared light, etc.). The sensitivity may comprise a broad or narrow bandwidth, as desired and set by the chemistry. In variations where the matrix material binding segment may be both activated and deactivated, the photosensitive segment may be light sensitive to multiple, distinct regions of the visible spectrum. For example, red light may be used to activate matrix material binding and green light may be used to prevent, or reverse, matrix material binding.

The photosensitive segment may comprise any chemistry enabling light sensitivity, i.e., photochemistry. Examples of possible photochemistry molecules that may comprise the photosensitive segment include, but are not limited to: fluorescein, rhodamine, cyanines, squaraines, napthalenes, coumarins, oxadiazoles, anthracenes, pyrenes, phenoxazines, acridines, tetrapyrroles, and dipyrromethenes (e.g., BODIPY) and azadipyrromethenes (Aza-BODIPY) Dependent on implementation, the photosensitive segment may comprise anyone, or combination, of these or other photochemistries.

The patterning material may comprise a matrix material binding segment. The matrix material binding segment may function in binding the matrix material. The matrix material binding segment may comprise any molecule(s) that can bind, or enable, binding of the matrix material. In some variations, the matrix material binding segment may be always active, such that the matrix material binding segment of the patterning material always binds to the matrix material. In one variation, the matrix material binding segment may be turned on, or off (e.g., by allosteric binding or photoactivation). In some variations, the matrix material binding segment may be “positively activatable”, such that binding only occurs once the matrix material binding segment has been activated. In a second variation, the matrix material binding segment may be “negatively activatable”, such that latent patterning material may initially bind to the matrix material, but through activation (e.g., photoactivation), the patterning material becomes unable to bind to the matrix material and unbinds from the matrix material. In a third variation, the matrix material binding segment may be both positively activatable and negatively activatable, such that the patterning material may be able to change conformations such that it can be made to bind and unbind from the matrix material. For example, the matrix material binding segment may be connected to one, or more, photosensitive segments sensitive to different bands of light. In this example, photoactivation by a first band of light (e.g., blue light) may activate the matrix material binding segment such that it can bind the matrix material, and photoactivation by a second band of light (e.g., red light) may deactivate the matrix material binding segment such that it cannot bind the matrix material.

In some variations, the method may include leveraging the reaction for matrix material binding by the patterning material. Dependent on the reactive group segment, the photoreaction of a patterning material (e.g., chromophore) and a reactive intermediate facilitates binding of the matrix material via a radical reaction. By controlling the concentration of the reactive intermediate, the rate of patterning material binding to the matrix material may be manipulated.

Block S122, which includes dispersing the patterning material through the matrix material, functions to expose the patterning material throughout the material of the matrix material such that patterning can occur on surfaces and within the matrix material. In some variations, dispersing the patterning material through the matrix material S122 deposits the patterning material homogeneously throughout the matrix material. This may be done by flowing the patterning material through the matrix material until the matrix material is saturated with the patterning material. In negatively activatable variations, the matrix material binding segment of the patterning material binds to the matrix material to the level of saturation. In positively activatable variations, the matrix material binding segment needs to be activated for matrix material binding and may thus diffuse freely through the matrix material.

Alternatively, dispersing the patterning material through the matrix material S122, may enable inhomogeneous deposition of the patterning material. For example, unidirectional flow (e.g., using microfluidics) may enable high concentration deposition on the side of the matrix material where the material enters the matrix material and low concentration deposition on the side of the matrix material where material flows out, creating a gradient of patterning material. Through the use of directional flows, any desired gradient deposition may be implemented dependent on the matrix material geometry. By limiting the flow over a certain time period, a latent patterning material concentration gradient may be created through the matrix material. Gradient deposition of the patterning material may enable forming gradients in the final nanofabrication (e.g., in the construction of optical primitives such as lenses).

Block S124, which includes photoactivating the patterning material, may be a component of patterning the matrix material S120. Photoactivating the patterning material s124 functions in mapping the shape of the structure of the fabrication with bound patterning material. This establishes the placement of the patterned material and accordingly may be used in establishing location of the reactive group particles throughout the matrix material. That is, the bound patterning material may thus demarcate the shape and structure of the desired fabrication within diffusing unbound latent patterning material. Additionally, different concentrations of patterning material may also demarcate gradients in the desired fabrication. Dependent on the implementation, the demarcation may comprise the general shape/structure of the desired fabrication, or the negative (e.g., mold) of the general shape/structure of the desired fabrication. In preferred variations, unbound patterning material may be washed away. Photoactivating the patterning material S124, comprises shining a focused light, or light beam, of the appropriate wavelength such that desired photosensitive segments of the patterning material are activated. Photoactivating the patterning material S124 may include both spatial focus and exposure time of light beam(s). Spatial focus of light beam(s) may be used to physically shape the desired fabrication (or its negative space). The exposure time of light beams (i.e., length of time the beam is focused in a given region) may be used to “shape” the concentration of material in a given region—that is, enable deposition (or removal) of different concentrations of patterning material in a given region.

The effectiveness of photoactivating the patterning material may be significantly dependent on how light is administered to the patterning material. By leveraging the triplet excited state lifetime of the patterning material, the efficiency of photoactivating the patterning material may be significantly improved. In some variations, photoactivating the patterning material includes providing light pulses that are separated by an amount of time less than the triplet excited state of the patterning material. Dependent on the implemented patterning material this pulsing rate may vary. For chromophores, the lifetime of the triplet excited state is typically between microseconds and picoseconds.

In a first, positively activatable variation, photoactivating the patterning material S124, may enable binding (e.g., at the matrix material binding segment) of the patterning material to the matrix material. In a second, negatively activatable variation, photoactivating the latent patterning material S124 may enable release (e.g., at the matrix material binding segment) of the latent patterning material from the matrix material.

As part of the first variation, photoactivating the patterning material S124 may occur concurrent to dispersing patterning material through the matrix material S122, such that photoactivated regions with latent patterning material bind to the matrix material (e.g., at the activated matrix material binding segment), wherein other non-activated patterning material flows away, or is washed away.

In a first implementation of the first variation (positively activatable variation), block S124 is implemented such that the region that coincides with the actual design of the fabrication is photoactivated. That is, only regions that demarcate the shape and structure of the fabrication are photoactivated, and thus the patterning material stays bound only to the regions that demarcate the shape and structure of the fabrication.

In a second, negative, implementation of the first variation (positively activatable variation), block S124 is implemented such that the regions that do not coincide with the actual design of the fabrication are photoactivated. That is, only the negative regions, i.e., regions that do not coincide with the fabrication are photoactivated. In this second implementation, the latent patterning material binds to the negative of the desired fabrication, and thus demarcating the mold for the fabrication.

As part of the second, negatively activatable, variation, the patterning material may be initially dispersed throughout the matrix material such that the matrix material is fully or partially saturated and bound. Photoactivating the patterning material S124 may then be implemented to release the unwanted patterning material which may then be washed out, if desired.

In a first implementation of the second variation (negatively activatable variation), block S124 is implemented such that the regions that do not coincide with the actual design of the fabrication are photoactivated. That is, only the negative regions, i.e., regions that do not coincide with the fabrication are photoactivated, thereby releasing patterning material from the negative regions. In this first implementation, the patterning material stays bound to the region demarcating the desired fabrication, wherein the negatively photoactivated latent patterning material is washed away.

In a second, negative, implementation of the second variation (negatively activatable variation), block S124 is implemented such that the region that coincides with the actual design of the fabrication is photoactivated. That is, only regions that demarcate the shape and structure of the fabrication are photoactivated, thereby releasing the latent patterning material that demarcates the shape and structure of the fabrication. In this second implementation, the patterning material stays bound to the negative regions, i.e., regions that do not coincide with the fabrication, and thus demarcating the mold for the fabrication.

In “simpler” fabrication implementations, block S124 may be implemented a single time such that the structure of the fabrication is completely mapped onto the patterning material. Dependent on the complexity of the fabrication (e.g., multiple material fabrications, complex 3D structures, gradients, etc.), photoactivating the patterning material S124 may comprise a series of photoactivation steps wherein certain regions of the latent patterning material become binding activated/binding inactivated, multiple times, forming both the positive and/or negatives of regions of the fabrication. In some variations, patterning the matrix material S120 may additionally include alternating steps of binding seed material S130.

Photoactivating the patterning material S124 may additionally be used to provide the framework for creating gradients in the fabrication. Photoactivating the patterning material S124 preferably includes both spatial and temporal activation of the patterning material. By shining a light beam on a specific region of the patterning material for a longer period of time, and/or at a greater intensity, a greater concentration of the latent patterning material become light-activated in a given region, thereby enabling a greater concentration of patterning material bound to one region of the matrix material. Gradient implementations may be particularly useful for fabrication of lens and prisms. By implementing increasing/decreasing time periods of light activation over a given region of space, a concentration gradient of bound patterning material may be created.

In some variations, patterning a matrix material S120 may include incorporating lithography techniques. Incorporating lithography techniques may function to provide a more precise and coordinated method for photoactivating the patterning material S124, wherein the lithography technique helps determine how and where the patterning material is photoactivated. Incorporating lithography techniques may provide, up to nanometer precision in patterning the matrix material with the patterning material. Dependent on the implementation, this incorporating lithography techniques may comprise a photolithography technique (also referred to as one photon lithography), multi-photon lithography (also referred to as two, three, four, etc. photon lithography), or some combination of lithography techniques for photo-activating the latent patterning material S124. Additionally, dependent on the desired implementation, incorporating lithography techniques may be used to create either positive or negative patterning, or both. Dependent on implementation, incorporating lithography techniques may comprise utilization of a prefabricated “mask”.

In some variations, incorporating lithography techniques may include incorporating a single photon lithography technique. A single photon lithography technique may comprise using a photon emitter (i.e., a single light source such as an LED) for photoactivating the latent patterning material S124. Dependent on implementation, any single photon lithography technique, or multiple techniques, may be incorporated. Examples include: contact lithography, projection lithography (e.g., direct light projection, or tomographic lithography), interference/holographic lithography, and phase mask lithography.

In one implementation, incorporating lithography techniques comprises incorporating contact lithography. In this implementation, a prefabricated mask is implemented (wherein a mask may be fabricated prior to, or as part of the implementation). The mask may then be positioned in contact, or in proximity, to a photosensitive substrate such that light that passes through a light pattern is transferred through the mask and onto the photosensitive substrate. This can be achieved by illumination either from a point light source, a focused light source, a diffuse light source, or a collimated light source. Dependent on implementation, the light source may be incorporated from any desired angle.

In another implementation, incorporating lithography techniques may comprise incorporating projection lithography. In this implementation, the prefabricated mask may be implemented (wherein the mask may be fabricated prior to, or as part of the implementation). Alternatively, a digital equivalent mask (e.g., maskless lithography, micromirror device, spatial light modulator, or phase mask) may be incorporated. The mask may be used in order to create a 2D or 3D pattern of light that is projected onto the photosensitive substrate through the use of refractive, diffractive, or reflective optics. The optics may magnify, reduce, or directly transfer the pattern of light. Projection may be achieved by either full illumination of the mask at once or by scanning the region of illumination (e.g., a line) gradually over the mask and/or over the photosensitive substrate. Examples of projection lithography include: Extreme Ultraviolet Lithography, Immersion Lithography, and Direct Light Projection and projection tomography (a method for creating a 3D pattern by projecting light from multiple angles).

In some variations, incorporating lithography techniques comprise incorporating interference lithography (also referred to as holographic lithography). In these variations, the interference of two or more coherent beams of light in order to generate a periodic pattern in 2D or 3D. This interference may be generated by splitting and recombining beams through the use of reflective, refractive, or diffractive optics.

In some variations, incorporating lithography techniques comprise incorporating phase mask lithography. In this implementation, a prefabricated mask (wherein the mask may be fabricated prior to or as part of the implementation), or other structure, may be implemented. The use of the mask, or other structure, may be used to modulate the phase of light using a 2D or 3D structure in order to project a holographic image that is patterned into the photosensitive substrate.

In some variations, incorporating lithography techniques may include incorporating a multi-photon lithography technique (also referred to as direct laser writing technique). The multi-photon lithography technique may comprise using light for photoactivating (or deactivating) the patterning material S124, wherein two (or more) photon absorption is utilized to excite the photosensitive segment. Dependent on implementation, any number of photons may be used in multi-photon lithography, i.e., two-photon, three-photon, or n-photon excitation in order to pattern the photosensitive substrate. Dependent on implementation, any multi-photon lithography technique, or multiple techniques, may be incorporated. Examples include: point-scanned multi-photon lithography, multifocal multi-photon lithography, holographic multi-photon lithography, and temporally focused multi-photon lithography.

In some variations, incorporating lithography techniques comprise incorporating point-scanned multi-photon lithography. Incorporating point-scanned multi-photon lithography may include scanning a single point of multi-photon excitation within the photosensitive substrate mechanically, electro-optically, or acousto-optically.

In some variations, incorporating lithography techniques comprise incorporating multifocal multi-photon lithography. Multifocal multi-photon lithography may comprise using diffractive optical elements or lens arrays to generate multiple foci of multi-photon excitation, which then are projected into the photosensitive substrate and mechanically, holographically, electro-optically, or acousto-optically scanned to generate a pattern.

In some variations, incorporating lithography techniques comprise incorporating holographic multi-photon lithography. holographic multi-photon lithography may comprise using a digital element such as a DMD or SLM positioned in the Fourier plane of the optics to allow for the projection of multi-photon excitation patterns (i.e., holograms) into the photosensitive substrate. These projected holograms may be altered in order to generate any pattern in addition to being scanned around in the substrate mechanically, electro-optically, or acousto-optically.

In some variations, incorporating lithography techniques comprise incorporating temporally focused multi-photon lithography. Temporally focused multi-photon lithography may comprise using pulses of light that are temporally defocused and then refocused within the photosensitive substrate in order to create a pattern. The light pattern is generated by the use of either a mask or a digital mirror device which can be illuminated in its entirety for a full frame pattern, or partially, such as with lines/points of light scanned across the surface in order to transfer the pattern into the photosensitive material.

In some variations, setting up the matrix material may include setting up a swollen matrix material (i.e., a hydrated matrix material). In these variations, the method may further include mechanically deforming (e.g., compressing) the swollen matrix material before and during photoactivating the matrix material S124. Mechanical deformation of the swollen concurrent to photoactivation may function to provide a higher resolution patterning in the uncompressed dimensions.

Block S130, which includes binding a seed material within the matrix material, functions by dispersing and enabling binding of a seed (also referred to as nucleator) material to the reactive group, thereby providing a nucleation site. In method variations that include patterning a reactive group within the matrix material, block S130 may include: binding the seed material within the matrix material comprises dispersing the seed material and binding the seed material to the reactive group within the matrix material. In variations that do not include patterning the matrix material S120, binding a seed material within the matrix material S130 may initiate dispersal and binding of the seed directly onto the matrix material.

The seed material (or nucleator) may generally be any compound that localizes (or binds) to the reactive group and enables desolubilization and deposition of a precursor reagent and/or a desired final compound in the implemented thermodynamic conditions. The seed material in some variations serves as a precursor metal and the step may include performing precursor metal deposition through the body (or within a region/surface) of the matrix material. Examples of possible seeds include: gold, silver, copper, cadmium sulfide, palladium, platinum, and/or mercury. Accordingly, the seed material may be selected from a set of gold, silver, copper, cadmium sulfide, palladium, platinum, and/or mercury (or any suitable subset of these such as gold, silver, and copper). These seed materials are preferably in nanomaterial form. They can be deposited or grown on patterned (or otherwise prepared) regions of the matrix material. For example. Gold nanomaterials may be grown on onto —OH or NH2 groups. The growth of these seed material/metals may be grown onto template material conjugated to the matrix material or patterned regions. For example, gold may be grown onto gold nanomaterials conjugated to the patterned regions.

The seed material by reacting (or otherwise bonding via non-chemical mechanisms) with the reactive group preferably becomes distributed within the matrix material according to the dispersion of the reactive group. The seed material may be uniformly distributed within the matrix material if a uniform pattern was used. Accordingly, binding the seed material S130 may include binding the seed material within the matrix material is bounded substantially uniformly through the matrix material. The seed material may alternatively have any suitable type of patterning.

Block S140, which includes growing a precursor reagent, functions in aggregating the precursor reagent to nucleation sites established by the seed material. The precursor reagent is grown at the nucleation sites established in Block S130. Growing a precursor reagent S140 may include dispersing the precursor reagent through the matrix material using any desired method. Once the seed is bound and a nucleation event occurs, the precursor reagent may aggregate and grow on, or around, the nucleation site.

In some variations, a nucleator is not required and the precursor reagent may directly bind to the reactive group, initiate nucleation, and grow by itself. As such, in some variations, the processes block S130 and S140 may be the same step or even S130 may be unnecessary.

In some variations, growing the precursor reagent includes preparing or providing a solution of the precursor reagent (i.e., a precursor reagent solution) and soaking the matrix material in the solution of the precursor reagent.

Dependent on variation, the growth of the precursor reagent may be controlled via controlling concentration, time, and conditions (e.g., elevated or lowered temperatures or pressures). On the simplest level, a fixed concentration of the precursor reagent may be dispersed evenly throughout the gel and allowed to aggregate and grow for a set amount of incubation time at a known temperature, prior to washing away unbound precursor reagent. Increasing, or decreasing, the incubation time, may thus (on average) increase, or decrease, the amount of precursor growth around the nucleation sites. For homogeneous growth, the amount of precursor reagent dispersed throughout the gel may be increased (or decreased) to change the amount of precursor reagent growth. Other methods may be used to modify growth as desired (e.g., temperature, pressure, flow).

Generally, the precursor reagent may be any compound that can directly deposit out of solution onto the gel or deposit in proximity of the seed. In many variations, the precursor reagent is a metal. In some of these variations, the precursor reagent is a transition metal. In other variations, the precursor reagent is an alkali metal, alkaline earth metal, or metalloid. Examples of possible precursor reagents include, but are not limited to: silver, copper, iron, and gold. The selection may depend on the seed material and the desired produced nanomaterial. In one variation, the seed material is gold nanomaterials, and the precursor reagent is silver. In another variation, the seed material may be silver nanomaterials and the precursor reagent is also silver. In this variation, the S130 or S140 may be skipped. However, S130 and S140 may be performed to grow the compounds bound within the matrix material. In one example, S130 may start with 1.4 nanometer gold, and then growing silver during S140 grows to between 3-300 nanometers.

Block S150, which includes adding a chalcogen, functions to react with the precursor reagent via an ion exchange, thereby forming a precursor reagent chalcogenide. In variations where the precursor reagent is a transition metal, or alkali metal, adding a chalcogen S150 may result in forming a metal chalcogenide. In some variations, the chalcogenide may be a Perovskites which is a sub class of Chalcogenide with a particular crystal structure.

Adding a chalcogen S150 may comprise adding any of the chalcogens from group 16 of the periodic table, adding the anionic variant of a chalcogen, or a salt of the of a chalcogen that dissolves into the anionic variant of the chalcogen in solution. Examples of the chalcogen include: oxygen, sulfur, selenium, tellurium, and polonium. In one example, wherein the precursor reagent is silver, adding a chalcogen S150 comprises adding an anionic variant of oxygen, thereby forming silver oxide. In another silver precursor reagent example, adding a chalcogen S150 comprises adding an anionic variant of sulfur, thereby forming silver sulfide.

Block S160, which includes adding a final compound, functions to provide the desired molecule(s) to replace the precursor reagent chalcogenide in the matrix material. Addition of the final compound may initiate the exchange of the precursor reagent, or precursor reagent chalcogenide, with the desired final compound, forming a new chalcogenide compound composition. In most variations, the quantity of the final compound will be proportional to the quantity of the precursor reagent in the precursor—chalcogenide nanomaterial (e.g., quantity due to growth of the precursor reagent). The final compound may be a mixture, alloy or composite nanomaterial containing multiple cations and optionally anions. In some variations, it may multiple different cations and/or different anions. This may be used to produce a wide variety of types of nanomaterial compositions (e.g., particles or nanostructures). In some variations, there may be multiple different Anions and Cations. The ion exchanges may enable core-shell composites and other forms.

Adding the final compound may be used in establishing nanomaterials of the form C×E within the matrix material, where C is any metal selected from the set of metal or metalloid (e.g., such as Alkali metals, Alkinline metals, Transition metals, post-transition metals, or metalloids like Sb) and where E is a group VI atom. Prior to introducing the final compound (e.g., the metal or metalloid), the matrix material is preferably patterned with (or otherwise has deposited within it) bounded compounds of the form M×E, where E is a group VI atom, and M preferably being another metal (e.g., gold, silver, copper, etc.). In some variations, the final compound may be a singular compound composition that is added (e.g., introduced via solution). In some alternative variations, a mixture of multiple final compounds may be introduced either in a mixture or in sequential exposure.

The final compound is introduced in a suitable material form, such as a cationic salt, and through the chemical exchange of the precursor reagent or precursor reagent chalcogenide, forms a final nanomaterial composition.

The final compound may be any desired atom, molecule, or composition of molecules, wherein the choice of precursor reagent and chalcogen may be chosen to enable appropriate reaction with the final compound. In some variations, the final compound may comprise a compound (e.g., pre-formed metal-chalcogenide nanomaterial or material) capable of directly binding to the matrix material. In these variations, adding a final compound S160 may be the only required step after preparing the matrix material S110. Alternatively, the final compound may be a compound that can be directly grown on the reactive group (e.g., silver). In these variations, adding a final compound S160 may be equivalent to growing a precursor reagent S130 and block S150 may be unnecessary. In one variation, the final compound is silver. A silver final compound may be used wherein replacing the precursor reagent chalcogenide with the final compound results in silver oxide or silver sulfide nanomaterials or any suitable form of silver chalcogenide nanomaterials. In some variations, the final compound may be a metal or metalloid compound. The final compound may be a cation or an anion. In some variations, this final compound may be mixture. The final compound may include multiple different cations, multiple different anions, and/or a mixture of different cation(s) and anion(s). This may be one approach to forming a nanomaterial composition that is a mixture, alloy, or composite.

In some variations, adding a final compound S160 may comprise adding multiple, unique compounds. In these variations, block S120-S150 may be implemented multiple times (e.g., once for each compound). In one variation, the final compound is cadmium. A cadmium final compound may be used wherein replacing the precursor reagent chalcogenide with the final compound results in cadmium sulfide nanomaterials or any suitable form of cadmium chalcogenide nanomaterials. This process may use silver as an intermediary, wherein block S160 may include adding a silver final compound to achieve silver sulfide (or other suitable silver chalcogenide) as an intermediary and then adding a ligand to facilitate a cation exchange to go from silver sulfide to cadmium sulfide. The ligand used in some variations could be a Phosphine Ligand or any of the suitable ligand variations described herein.

In some variations, adding a final compound S160 may include adding an intermediary compound, or compounds. Adding an intermediary compound may function in a similar manner as adding the final compound S160, except for block S160 may be repeated until an actual final compound is added. This may occur when an exchange from the precursor reagent chalcogenide to the desired final compound is not thermodynamically feasible. In these variations, adding an intermediary compound can replace the precursor reagent chalcogenide. Once this occurs, block S150 may be called again to form a new intermediary chalcogenide. If necessary, multiple intermediary steps may be incorporated in this fashion prior to arriving at the final compound.

Generally, the final compound may be any atom, molecule, or composition of molecules that can exchange with the precursor reagent or the precursor reagent chalcogenide. In variations, wherein the precursor reagent is a transition metal, the final compound may be a metal (e.g., Cd2+, Zn2+ etc.). In other variations, the final compound may be a non-metal compound. In one example, the final compound may comprise a cubic boron arsenic.

In some variations, the method may include adding a ligand in solution S170. This may be done when adding the final compound. They may not be added coincidently and may be added in any suitable order such that they facilitate the cooperative reaction involving the final compound and the ligand with the bounded compound (e.g., an M×E compound) within the matrix material. The ligand may facilitate exchange (e.g., cation exchange) of the precursor reagent chalcogenide with the final compound. The ligand can be any other compound that facilitates cation exchange. Examples of possible ligands include: n-alkylphosphonic acids (such as n-hexylphosphonic, n-octylphosphonic, n-decylphosphonic, n-tetradecylphosphonic and n-octadacylphosphonic acids); a phosphine (e.g., tri(n-alkyl)phosphines like tri(octyl)-, tri(butyl)phosphine, Tris(3-hydroxypropyl)phosphine (THPP)); phosphines with the formula PR3, where R=Et; PrOH; Me; nBu; nOct; Ph; PhMe; PhOMe, and corresponding phosphites PR3O (e.g., tri(octylphosphine); oxide fatty carboxylic acids (e.g., lauric, myristic, palmitic and stearic acids); unsaturated carboxylic acids (e.g., oleic acids); primary, secondary, tertiary alkyl amines (e.g. octylamine, dioctylamine, triethylamine etc.); and n-alkylphosphonic acids (such as n-hexylphosphonic, n-octylphosphonic, n-decylphosphonic, n-tetradecylphosphonic and n-octadacylphosphonic acids).

In some variations, the method may be used in producing nanomaterials within the matrix material. In some variations, the method may be further adapted for production of nanomaterials in isolation without the matrix material (e.g., the gel formation). In this variation, the method may additionally include, after forming the final compound in the matrix material, breaking down the matrix material. This functions to remove the material of the matrix material leaving the nanomaterials that were formed. The matrix material may be cleaved/degraded using various approaches in including chemically breaking down (Acid reaction, Base reaction, reduction, dissolving), light, heat (e.g., melting), mechanically (e.g., grinding, mashing, sonication centrifugation) and/or otherwise breaking down the matrix material so as to leave the produced nanomaterials.

As used herein, first, second, third, etc. are used to characterize and distinguish various elements, components, regions, layers and/or sections. These elements, components, regions, layers and/or sections should not be limited by these terms. Use of numerical terms may be used to distinguish one element, component, region, layer and/or section from another element, component, region, layer and/or section. Use of such numerical terms does not imply a sequence or order unless clearly indicated by the context. Such numerical references may be used interchangeable without departing from the teaching of the embodiments and variations herein.

As a person skilled in the art will recognize from the previous detailed description and from the figures and claims, modifications and changes can be made to the embodiments of the invention without departing from the scope of this invention as defined in the following claims.

We claim:

1. A method comprising:
preparing a matrix material;
binding a seed material within the matrix material, establishing nucleation sites;
at the nucleation sites, growing a precursor reagent;
adding a chalcogen to form precursor reagent chalcogenide;
adding a final compound, facilitating an ion exchange and replacing the precursor reagent chalcogenide with the final compound to form a nanomaterial composition.

2. The method of claim 1, wherein the seed material is selected from a set of gold, silver, and copper.

3. The method of claim 1, wherein adding the final compound, facilitating the ion exchange and replacing the precursor reagent chalcogenide with the final compound further comprises establishing nanomaterials of the form C×E within the matrix material, where C is any metal or metalloid, and where E is a group VI atom.

4. The method of claim 1, further comprising adding a ligand in solution to the matrix material thereby facilitating ion exchange.

5. The method of claim 1, wherein adding a chalcogen to form precursor reagent chalcogenide and adding are performed at a temperature range of 0° C.-1000° C.

6. The method of claim 1, wherein binding the seed material within the matrix material is bounded substantially uniformly through the matrix material.

7. The method of claim 1, further comprising, prior to binding the seed material, patterning a reactive group within the matrix material; and wherein binding the seed material within the matrix material comprises dispersing the seed material and binding the seed material to the reactive group within the matrix material.

8. The method of claim 7, wherein patterning the reactive group within the matrix material comprises dispersing a patterning material with the reactive group through the matrix material and photoactivating the patterning material.

9. The method of claim 8, wherein the reactive group is a chromophore selected from the set of chromophores comprising fluoresceins, rhodamines, squaraines, and cyanines.

10. The method of claim 1, further comprising establishing a second compound within the matrix material, which comprises:
binding a second seed material within the matrix material, establishing second nucleation sites;
at the second nucleation sites, growing a second precursor reagent;
adding a second chalcogen to form second precursor reagent chalcogenide;
adding second final compound, facilitating a second ion exchange and replacing the second precursor reagent chalcogenide with the second final compound.

11. The method of claim 1, further comprising breaking down the matrix material leaving nanomaterials of the final compound.

12. The method of claim 1, wherein the seed material is gold nanomaterials, and the precursor reagent is silver.

13. The method of claim 1, wherein the seed material is silver nanomaterials, and the precursor reagent is silver.

14. The method of claim 1, wherein the final compound is silver.

15. The method of claim 14 wherein replacing the precursor reagent chalcogenide with the final compound results in silver oxide or silver sulfide nanomaterials.

16. The method of claim 1, wherein the final compound comprises cadmium; further comprising adding a phosphine ligand solution; and wherein replacing the precursor reagent chalcogenide with the final compound results in cadmium sulfide.

17. The method of claim 1, wherein the final compound is one of a mixture; and the nanomaterial composition is an alloy, composite, or mixture.

18. The method of claim 17, wherein the final compound contains multiple cations and/or anions.

19. The method of claim 17, wherein the final compound contains multiple different cations.

20. A method comprising:
providing a gel matrix;
patterning a reactive group within the gel matrix;
binding a seed material to reactive groups within the gel matrix, the seed material selected from a first set of gold nanomaterials, silver nanomaterials, and copper nanomaterials;
binding a precursor reagent selected from materials to the seed material;
adding a chalcogen to form a precursor reagent chalcogenide at sites of the precursor reagent via an ion exchange;
adding nanomaterial compound and a ligand solution and facilitating cation exchange replacing the precursor reagent chalcogenide with nanomaterials of the nanomaterial compound.
